(19) United States
(12) Patent Application Publication
(10) Pub. No.: US 2008/0251017 A1
(43) Pub. Date: Oct. 16, 2008

(54) Fastening Unit for Ignition Units and Device for Carbon Deposition

(76) Inventors: Gunter Schneider, Besigheim (DE); Alexander Schattke, Bursa (TR); Rainer Feuerfeil, Gerlingen (DE)

Correspondence Address: KENYON & KENYON LLP, ONE BROADWAY, NEW YORK, NY, 10004, US

(21) Appl. No.: 11/628,581

(22) PCT Filed: Apr. 26, 2005
(86) PCT No.: PCT/EP2005/051854

§ 371 Date: Jan. 7, 2008

(30) Foreign Application Priority Data
Jun. 18, 2004 (DE) 10 2004 029 525.5

(51) Int. Cl. H05H 1/38; C23C 16/509; C23C 16/515

(52) U.S. Cl. 118/723 E; 315/111.21; 313/231.41

(57) ABSTRACT

A fastening unit for fastening ignition units as part of a device for carbon deposition is provided, the fastening unit of the device having a first and a second holder, the ignition unit being situated between the two holders, and the holders being held together by at least one fastening device. The first holder has a first plane that has a first angle between 0° and 45° in relation to the longitudinal axis of the first holder. The ignition unit is situated such that the end surface of the ignition unit forms a right angle to the first plane.

### FIELD OF THE INVENTION

The present invention relates to a fastening unit for fastening an ignition unit as part of a device for carbon deposition.

### BACKGROUND INFORMATION

A number of physical deposition methods are known for the coating of workpieces, in particular components that are subjected both to high tribological loading and at the same time to additional loading of various types, e.g., temperature or cavitation. From the field of plasma coating technology, two different methods are to be noted for producing carbon layers that are free of metals and of hydrogen (known as tetrahedral coordinated amorphous carbon, or ta-C): deposition of graphite targets by sputtering or by arc vaporization.

However, the sputtering method is characterized by a lower deposition rate, for which reason this method is not suitable for economic use.

In an arc vaporization process, the material to be vaporized is typically applied to cathodic potential, while a special electrode is present as the anode; the wall of the coating chamber can also act as the anode. For the vaporization of the target material, an arc is ignited between the anode and the cathode that heats the cathode locally at the focus point, which can be recognized as a focal spot on the cathode, so strongly that the target material goes over into the vapor phase and is deposited on a workpiece. In order to produce the arc between the anode and the cathode, an ignition device is required.

In addition to mobile ignition devices, also known are ignition electrodes situated in stationary fashion in the vicinity of the target cathode, between which an arc is ignited that then goes from the ignition electrode to the anode.

A controlled DC arc vaporization of carbon proves to be difficult, because the focus point of the arc tends to burn fixedly at one point of the target, and possibly to burn through it. It is also known that during vaporization what are known as droplets (macroparticles) result in an increased roughness of the coating on the workpiece. For these reasons, this method is also used only to a limited extent.

In a pulsed arc discharge, in contrast, the voltage between the anode and the cathode is applied in pulsing fashion, so that the focus point on the target is accelerated to approximately 100 times the speed of DC arc vaporization, thus avoiding fixed burning. The pulsed arc discharge has in general a pulse length in the millisecond range; in this way, the discharge is localized in the spatial vicinity of the ignition.

If it is desired to use the technology of pulsed arc discharge for large-surface targets, it thus makes sense to use a design having a plurality of individual ignition sources.

Published Russian patent document RU 2153782 describes a carbon plasma pulse source for depositing a carbon layer onto a workpiece, which pulse source has, among other components, a graphite cathode, an anode, a capacitive storage circuit, and at least two ignition units situated on the periphery of the graphite cathode. Through this system, in comparison to a device having only one ignition unit, the area coated with the carbon layer is expanded, and the thickness of the applied layer on the workpiece is simultaneously made more uniform. The ignition units are each made up of a rod-shaped metal electrode and an annular graphite electrode, respectively acting as the ignition cathode and the ignition anode. Between the ignition cathode and the ignition anode, there is situated a ring made of a dielectric material; this dielectric material is coated with an electrically conductive material on its side facing the target cathode. The longitudinal axis of each ignition unit is here oriented toward the corresponding region of the work surface of the target cathode, which is provided for the starting of the arc discharge. Due to this orientation, the end surface of the ignition unit at which the ignition takes place is inclined towards the target cathode at a particular angle.

If an exchange of, for example, a non-functioning ignition unit for a new ignition unit becomes necessary, care is to be taken that the original orientation is reproduced when installing the new ignition unit. This includes, in particular, the correct inclination of the ignition unit in relation to the target cathode, at a predetermined angle.

The Russian reference cited above, however, does not teach or suggest how the desired inclination of the ignition unit is to be achieved. In practice, it is desirable for the desired inclination of the ignition unit to be able to be achieved easily and quickly, and above all for readjustment of the inclination to be unnecessary after an exchange of ignition units. The required adjustment of the exchanged ignition units results in a high time and maintenance expense in the operation of the coating apparatus.

### SUMMARY

The fastening unit according to the present invention for fastening ignition units as part of the device for carbon deposition has the advantage that a simple exchange of the ignition units is enabled without requiring adjustment of the provided inclination of the newly installed ignition unit. An installation of an ignition unit using the fastening unit according to the present invention results automatically in the predetermined inclination of the ignition unit in relation to the target cathode of the coating apparatus. In addition, ease of handling of the fastening unit enables rapid exchanging even of a plurality of ignition units. In addition, an additional expense, e.g., for maintenance or monitoring of the fastening unit, is practically not necessary.

### BRIEF DESCRIPTION OF THE DRAWINGS

FIG. 1 shows a fastening unit in cross-section.

FIG. 2 shows a fastening unit having an installed ignition unit and a target cathode in cross- section.

FIG. 3 shows a first ignition unit in a perspective representation.

FIG. 4 shows a second ignition unit in a perspective representation.

FIG. 5 shows components of a device for carbon deposition.

FIG. 6 shows a top view of a target cathode having a cooling water circuit, a base electrode, and a plurality of ignition units.

### DETAILED DESCRIPTION

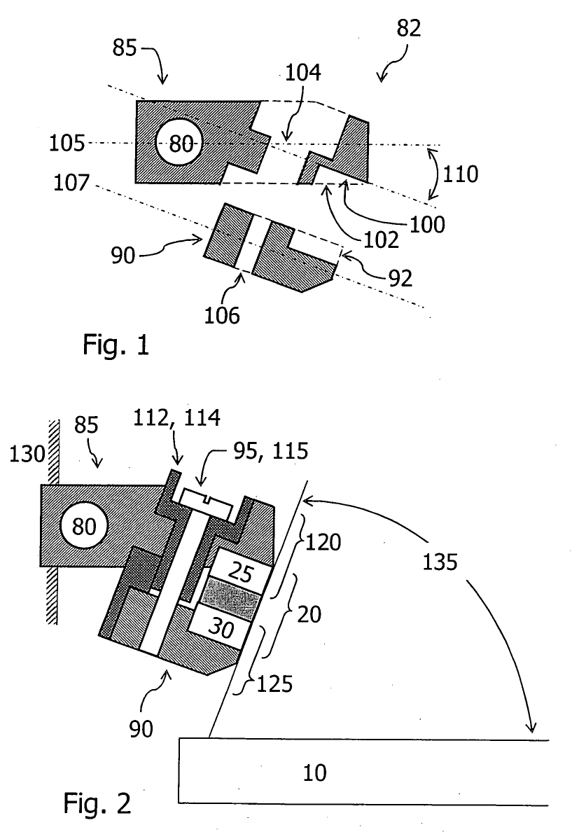

The fastening unit 82 shown in cross-section in FIG. 1 for an ignition unit, in particular of a carbon deposition device, has a first and second holder 85, 90. The two holders 85, 90 are held together by a fastening device 95, as is shown in FIG. 2. For both holders 85, 90, the length extension is greater than the thickness extension. As is shown in FIG. 1, the respective longitudinal axes 105, 107 run along the longitudinal extension of each holder 85, 90. The absolute length of first holder 85 is typically greater than that of second holder 90.

First holder 85 has a first bore 104 that runs continuously through the thickness of holder 85. Bore 104 is stepped, and has a center section having a smaller diameter. Bore 104 runs at an incline to the surface of holder 85 or to longitudinal axis 105. In addition, at an end area in the longitudinal extension of holder 85 a recess 102 is formed and is open toward second holder 90. Here, recess 102 has a shape such that recess 102 forms a wall on the lower side of holder 85, designated below as plane 100, that forms a first angle 110 of between 0° and 45° in relation to longitudinal axis 105 of first holder 85. An ignition unit can be inserted at least partly into this recess 102.

Second holder 90 likewise has a second bore 106 and a second recess 92. Bore 106 runs with a constant diameter perpendicular to the surface of second holder 90, or to its longitudinal axis 107. Bore 106 can run continuously through the thickness of holder 90. Recess 92 is formed at an end area in the longitudinal extension of holder 90, and is open toward recess 102 of first holder 85. Recess 92 has a wall that runs parallel to longitudinal axis 107 of second holder 90. The ignition unit can be inserted at least partly into this recess 92.

As can be seen from FIG. 2, the two holders 85, 90 are held together by a fastening device 95. Fastening device 95 is preferably a screw 115. For the attachment of fastening device 95, two bores 104, 106 are provided. Bores 104, 106 are typically aligned with one another. This can for example be achieved in that bore 104 of first holder 85 runs perpendicular to plane 100 and bore 106 of second holder 90 runs perpendicular to longitudinal axis 107 of second holder 90. Bores 104, 106 and the end surface of ignition unit 20 at which the ignition takes place then run parallel to one another. A plurality of fastening devices 95, in particular two, is also possible for a fastening unit 82. The number of bores 104, 106 then increases accordingly.

The two holders 85, 90 are situated such that recesses 102, 92 face each other. Ignition unit 20 is situated between the two holders 85, 90, and is simultaneously inserted at least partially into the two recesses 102, 92.

In addition, ignition unit 20 is situated between the two holders 85, 90 in such a way that the end surface of ignition unit 20 at which the ignition takes place forms a perpendicular to plane 100. Because plane 100, as already described, has a fixed angle 110 between 0° and 45° in relation to longitudinal axis 105 of first holder 85, this combination always results in a fixed angle of between 45° and 90° between the end surface of ignition unit 20 and longitudinal axis 105 of first holder 85.

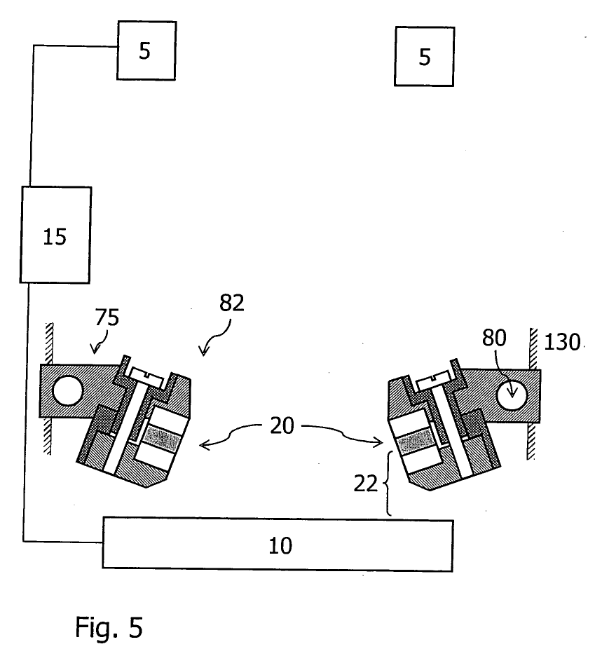

As an example, fastening unit 82 and a target cathode 10 of the device for carbon deposition are situated, as shown in FIG. 5, in such a way that longitudinal axis 105 of first holder 85 and the surface of target cathode 10 run parallel to one another. A second angle 135 resulting therefrom between the end surface of ignition unit 20 and the surface of target cathode 10 is then exactly 90° minus the value of first angle 110. A suitable value of second angle 135 is in particular between 45° and 90°.

After fastening device 95 is detached, ignition unit 20 can be exchanged. First holder 85 is connected fixedly to a support 130 of the device for carbon deposition. Therefore, the situation and the relative position of first holder 85 in relation to target cathode 10 need not be modified. After a simple exchange of the new ignition unit 20, the two holders 85, 90 are subsequently again held together by fastening device 95, and the desired inclination of ignition unit 20 is again achieved without any adjustment, due to the above-described features of fastening unit 82.

Support 130 of the device for carbon deposition can be formed by a framework inside the vacuum chamber, or can be a part of the chamber wall.

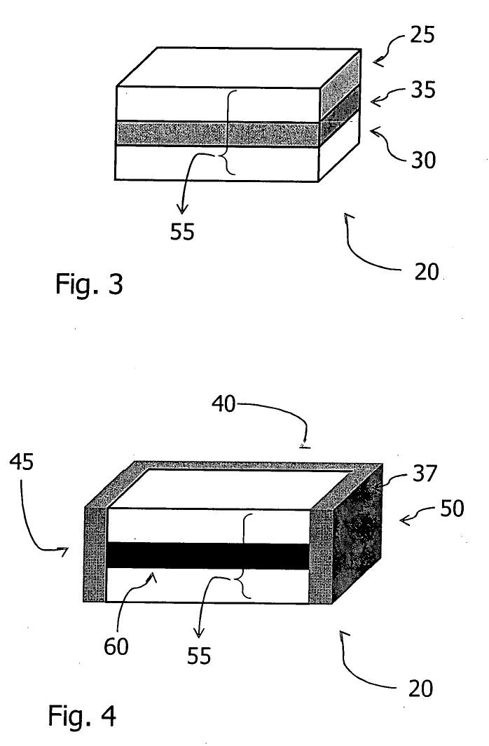

As an example, ignition units 20 having a planar construction are used, because additional advantages of the present invention result from this. As is shown in FIG. 3, an ignition unit 20 has two planar metallic electrodes 25, 30 situated parallel to one another, and a planar insulating ceramic 35 is situated in the intermediate space between electrodes 25, 30. Metallic electrodes 25, 30 can be made of arc-resistant materials, such as for example tungsten, tungsten/lanthanum, or graphite.

A second example embodiment of ignition unit 20 is shown in FIG. 4, in which the insulating ceramic is advantageously constructed in two parts. As already described, the first part is formed by a planar insulating ceramic 35. The second part of the insulating ceramic is a ceramic casing 37 that covers both rear side 40 and also side surfaces 45, 50 of ignition unit 20. In this way it is ensured that an ignition spark occurs only at the end surface 55 that is not covered by ceramic casing 37. The first and second part of the insulating ceramic can also be formed as a contiguous individual part.

Due to the planar construction of ignition unit 20, a linearly extended structure results for insulating ceramic 35 on the surface of ignition unit 20. In practice, its length is approximately up to 10 cm. If ignition unit 20 is ignited several times in succession, with each new ignition the ignition spark takes place at various points distributed statistically along the linearly extended structure. Thus, the focus point on target cathode 10 is also displaced somewhat in each ignition. In a simple manner, a homogenous exploitation of the entire surface of target cathode 10 is achieved, resulting finally in a uniform coating of a workpiece.

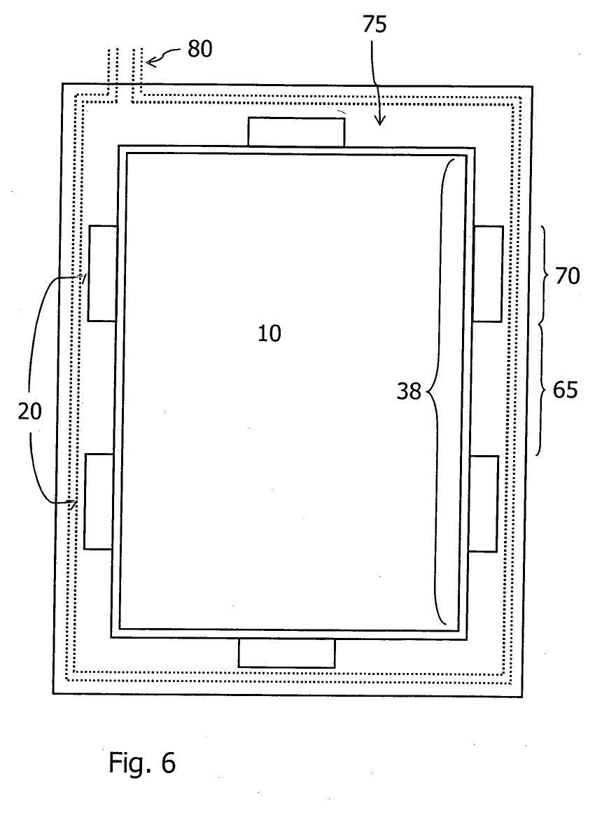

A further advantage results from a comparison of the required number of planar ignition units 20 to the number of non-planar ignition units, e.g., round ignition units that would be required. If target cathode 10 has in both cases the same length 38 (see FIG. 6), fewer planar ignition units 20 are required, because each individual planar ignition unit 20 homogenously wears away a larger surface on target cathode 10. A smaller number of ignition units 10 reduces the maintenance expense and increases useful life.

In addition, planar ignition units 20 can be situated very close to target cathode 10 due to their shape, and distance 22 of ignition unit 20 to target cathode 10 can be made smaller in comparison with a distance of a non-planar ignition unit to target cathode 10. In this way, the ignition reliability is significantly increased, and the coating process as a whole is more reliable.

In addition, in this example embodiment insulating ceramic 35 of ignition unit 20 is coated at end surface 55 with an electrically conductive material 60. When a current pulse is applied to ignition unit 20, a current path then results that is directed toward target cathode 10, because the conductive coating of insulator ceramic 35 partially vaporizes and a highly ionized plasma arises. This current path, formed from plasma, in turn enables an additional current path for the actual main discharge from target cathode 10 to anode 5, as is shown in FIG. 5. The partial consumption of the conductive material 60 on insulator ceramic 35 is compensated during the main discharge by a new coating, thus regenerating the conductive film. This process ensures the long-term stability of ignition unit 20 even in operation over a longer period of time.

For a reliable ignition, the poling of ignition electrodes 25, 30 should be applied such that a maximum potential difference is produced between ignition unit 20 and cathode 10. For this purpose, the metallic electrode 30 that is situated closer to target cathode 10 is used as the positive pole, and metallic electrode 25 situated further from target cathode 10 is used as the negative pole.

Due to a favorable situation of planar ignition units 20 with respect to target cathode 10, a homogenous wearing away of the target material, or a homogenous coating of a workpiece, can be further increased. FIG. 6 shows a target cathode 10 in a top view, a plurality of ignition units 20 being situated at the edge of target cathode 10.

In order to ignite the main discharge in a uniformly distributed fashion at various locations on the target surface, a plurality of ignition units 20 are situated along the target edge area in such a way that the overall effect of individual target units 20 results in an optimal, i.e., homogenous, wearing away over the entire area of target cathode 10. This procedure is enabled both by a variable distance 65 between ignition units 20 and also by the possibility of selecting suitable ignition units 20 having varying length 70 for use. Previously known undesirable fringe effects, such as the decreasing thickness of the coating at the upper and lower region of the target surface, can be compensated by a closer distance 65 of ignition units 20 in the corresponding areas.

FIG. 5 shows components of the device for carbon deposition. The device for carbon deposition is essentially made up of an anode 5, a planar target cathode 10, a pulsed energy source 15, a support 130 for fastening units 82, and at least two ignition units 20 and fastening units 82. Ignition units 20 are situated in the edge area of target cathode 10 (see also FIG. 6). Ignition units 20 are connected electrically to an ignition distributor (not shown) that controls the ignition of individual ignition units 20. When a current pulse is applied between the two electrodes 25, 30 with a sufficiently high voltage, a glow discharge takes place that starts the actual arc discharge from target cathode 10 to anode 5.

Pulsed energy source 15, typically realized by a bank of capacitors, is connected between target cathode 10, formed from carbon, and anode 5. The bank of capacitors is fed by a power supply unit (not shown) and at first remains charged, because there is a vacuum between anode 5 and target cathode 10, so that the circuit is not closed. For the ignition of an arc between anode 5 and target cathode 10, and thus for the wearing away of carbon from target cathode 10 in the direction toward anode 5, at least two ignition units 20 are provided.

A further advantage of planar ignition units 20 in combination with the fastening unit according to the present invention results from the possibility of introducing, in a simple manner, a common, continuous base electrode 75.

For this purpose, both holders 85, 90 are made of an electrically conductive material, fastening device 95 being electrically separated from at least one holder 85, 90 by an insulating element 112, in particular a ceramic insulating sleeve 114. Electrically conductive holder 85, 90 forms, together with contacting planar electrode 25, 30 of ignition unit 20, a common ignition cathode 120, or a common ignition anode 125. At least two ignition units 20 then have a common, continuous base electrode 75. For example, all negatively poled electrodes 25 of individual ignition units 20 are connected to one another and are thus electrically contacted.

Moreover, such a common, continuous base electrode 75 offers the possibility of integrating a cooling water circuit 80 into base electrode 75. As can be seen, for example, from FIG. 2 and FIG. 6, base electrode 75 has an inner conduit 80 that acts as a cooling water conduit. In this way, a cooling of all ignition units 20 is achieved in a simple manner. A cooling of ignition units 20 is required for stable long-term operation because ignition units 20 are exposed to a high degree of thermal loading, in particular given frequent ignitions.

1-12. (canceled)

13. A fastening unit for an ignition unit of a carbon deposition device, the ignition unit having two metallic electrodes and an insulating ceramic situated between the metallic electrodes, the fastening unit comprising:
a first holder and a second holder, wherein the ignition unit is situated between the first and the second holder; and
a fastening device for holding together the first holder and the second holder, wherein the fastening device is coupled to the first holder and the second holder;
wherein the first holder has a first surface plane that has a first angle of between 0° and 45° in relation to the longitudinal axis of the first holder, and wherein the first surface plane is perpendicular to an end surface of the ignition unit at which ignition takes place.

14. The fastening unit as recited in claim 13, wherein the first surface plane is a part of a wall of a first recess in the first holder, and wherein the ignition unit is inserted at least partly into the first recess.

15. The fastening unit as recited in claim 14, wherein the second holder has a second recess, and wherein the ignition unit is inserted at least partly into the second recess.

16. The fastening unit as recited in claims 15, wherein the first holder and the second holder each have a bore for coupling with the fastening device.

17. The fastening unit as recited in claim 16, wherein the bore of the first holder and the bore of the second holder are axially aligned with one another.

18. The fastening unit as recited in claim 17, wherein the fastening device is a screw.

19. The fastening unit as recited in claim 17, wherein the first holder and the second holder are made of an electrically conductive material.

20. The fastening unit as recited in claim 13, further comprising:
an insulating element, wherein the fastening device is electrically separated from at least one of the first holder and the second holder by the insulating element.

21. The fastening unit as recited in claim 20, wherein the insulating element is a ceramic insulating sleeve.

22. A device for carbon deposition, comprising:
an anode;
a target cathode made of carbon;
at least two ignition units and at least two fastening units, wherein each ignition unit is positioned, with the aid of a corresponding fastening unit, in an edge area of the target cathode, and wherein an end surface of each ignition unit at which ignition takes place faces the target cathode; and
a support element;
wherein each fastening unit has a first holder and a second holder, the first holder and the second holder being held together by at least one fastening device, and the first holder being connected fixedly to the support element, and wherein each ignition unit is situated between the first holder and the second holder of a corresponding fastening unit so as to be inclined in such a way that an end surface of each ignition unit encloses a selected angle in relation to the target cathode.

23. The device as recited in claim 22, wherein the selected angle is between 45° and 90°.

24. The device as recited in claim 23, wherein for each ignition unit, one of the first holder and the second holder forms a common ignition cathode together with a contacting electrode of the ignition unit.

25. The device as recited in claim 23, wherein the device is configured for depositing tetrahedral coordinated amorphous carbon layers.
